(19) United States
(12) Patent Application Publication
(10) Pub. No.: US 2007/0069310 A1
(43) Pub. Date: Mar. 29, 2007

(54) Semiconductor controlled rectifiers for electrostatic discharge protection

(75) Inventors: Ki-Whan Song, Seoul (KR); Jong-Duk Lee, Seoul (KR); Byung-Gook Park, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/525,021

(22) Filed: Sep. 22, 2006

(30) Foreign Application Priority Data
Sep. 26, 2005 (KR) 10-2005-0089345

(51) Int. Cl. H01L 29/76

(52) U.S. Cl. 257/409

(57) ABSTRACT

A silicon controlled rectifier (SCR) may include a first well and a second well formed within a substrate. A first junction region and a second junction region may be formed within the first well. A third junction region may include a first portion formed within the first well and a second portion formed within the substrate. A fourth junction region may include a first portion formed within the second well and a second portion formed within the substrate. A gate electrode may be formed on the substrate between the third junction region and the fourth junction region. A fifth junction region may be formed within a region of the substrate.

### PRIORITY STATEMENT

This application claims priority under 35 U.S.C. §119 to Korean Patent Application No. 10-2005-0089345, filed on Sep. 26, 2005 in the Korean Intellectual Property Office (KIPO), the entire contents of which are incorporated herein by reference.

### BACKGROUND OF THE INVENTION

1. Field of the Invention

Example embodiments of the present invention relate to silicon controlled rectifiers (SCRs) for electrostatic discharge (ESD) protection. At least some example embodiments of the present invention provide SCRs, which may have a lower trigger voltage and/or a higher holding voltage, and/or may be capable of ensuring more uniform turn-on characteristics between fingers when formed in a finger structure.

2. Description of the Related Art

Related art semiconductor integrated circuits fabricated using complementary metal oxide semiconductor (CMOS) technology may be increasingly sensitive to higher voltages and/or higher current caused, for example, by static electricity. The static electricity may be caused, for example, by contact with a human body. In some cases, a voltage and/or current in the integrated circuit caused by static electricity may destroy an insulating layer and/or short-circuit a channel, which may disable the integrated circuit.

To suppress such damage, conventional semiconductor integrated circuits may include an ESD protection circuit in input and output circuits. The ESD protection circuit may perform a function of suppressing the voltage and/or current caused by static electricity from impinging on internal devices of integrated circuits.

FIG. 1A is a cross-sectional view illustrating a related art grounded-gate NMOS for ESD protection. FIG. 1B is an equivalent circuit of the related art grounded-gate NMOS shown in FIG. 1A.

Referring to FIG. 1A, n+ junction regions 11 and 12 may be formed spaced apart within a p-type substrate 10 and a gate electrode 13 may be formed on the p-type substrate 10. The n+ junction regions 11 and 12 may be spaced apart from one another by a distance, and the gate electrode may be formed in the space between the n+ junction regions 11 and 12. A p+ junction region 14 may be formed within the p-type substrate 10, and may be spaced apart from the n+ junction region 12. A Shallow Trench Isolation (STI) layer 15 may be formed within the p-type substrate 10 between the p+ junction region 14 and the n+ junction region 12. The STI layer 15 may act as an insulator between the p+ junction region 14 and the n+ unction region 12.

An input/output terminal 1/O may be connected to the n+ junction region 11. The p+ junction region 14, the n+ junction region 11 and the gate electrode 13 may be connected to a common ground voltage VSS.

Referring to FIG. 1B, the gate electrode 13, the n+ junction region 12 and the n+ junction region 11 of FIG. 1A may form a gate, a drain and a source of an NMOS transistor, respectively. The p-type substrate 10, the n+ junction region 11 and the n+ junction region 12 may form a base, a collector and an emitter of a parasitic npn transistor Q, respectively. A parasitic resistor Rp may be formed between the p-type substrate 10 and the p+ junction region 14.

The related art grounded-gate NMOS for ESD protection may perform several operations for ESD protection. These operations will be described in more detail below. In FIG. 1A, for example, when static electricity is generated, a higher voltage may be applied to the input/output terminal I/O. This may cause a reverse-biased pn junction between the n+ junction region 11 and the p-type substrate 10 to break down, and a trigger current may flow from the n+ junction region 11, through the p-type substrate 10 and the p+ junction region 14 to the ground voltage VSS. The pn junction between the p-type substrate 10 and the n+ junction region 12 may be forward-biased, so that an ESD current flows from the input/output terminal I/O through the n+ junction region 11, the p-type substrate 10, and the n+ junction region 12, to ground VSS.

In another example, when static electricity is generated and a higher voltage is applied to the input/output terminal I/O, a trigger current may flow through the drain-gate of an NMOS transistor, the collector-base of a parasitic npn transistor Q, and a parasitic resistor Rp of FIG. 1B. This may cause voltages of the base of the parasitic npn transistor Q and the gate of the NMOS transistor to increase. When the voltages of the base of the parasitic npn transistor Q and the gate of the NMOS transistor reach a trigger voltage Vt, the NMOS transistor and the parasitic npn transistor Q may be switched on, and an ESD current may flow through the parasitic npn transistor Q.

When the voltage reaches and/or exceeds the trigger voltage Vt, as shown in FIG. 2, the grounded-gate NMOS transistor for ESD protection may begin to perform ESD protection.

In this example, the trigger voltage Vt may be a voltage at which a drive current of the grounded-gate NMOS transistor for ESD protection increases more rapidly.

Such a grounded-gate NMOS transistor for ESD protection may require current drivability capable of discharging the ESD current to ground VSS so as to carry out a safer and/or more reliable ESD protection. The current drivability may be proportional to the capacitance and the area occupied by the grounded-gate NMOS transistor for ESD protection.

As related art semiconductor integrated circuits become smaller through, for example, larger scale integrated techniques, reduced capacitance and/or area occupied by the grounded-gate NMOS transistor for ESD protection may be needed. However, as the capacitance and/or the occupied area of the grounded-gate NMOS transistor for ESD protection is reduced in size, the operational quality of the grounded-gate NMOS transistor for ESD protection may decrease.

An SCR may replace the grounded-gate NMOS transistor. The SCR may carry out more effective ESD protection with a smaller capacitance in a smaller area because of a current drivability approximately four to five times higher than the grounded-gate NMOS transistor.

FIG. 3A shows a structure of a related art SCR for ESD protection. FIG. 3B shows an equivalent circuit of the SCR for ESD protection of FIG. 3A.

Referring to FIG. 3A, an n-well 21 may be formed within a region of a p-type substrate 20. An n+ junction region 22 and a p+ junction region 23 may be formed within the n-well 21, and may be spaced far apart from one another. An n+ junction region 24 may be formed partly within the n-well 21 and the p-type substrate 20 at an interface of the n-well 21 and the p-type substrate 20.

An n+ junction region 25 may be formed within the p-type substrate 20, and may be spaced apart from the n+ junction region 24 by a distance. A gate electrode 26 may be formed on a surface of the p-type substrate 20 between the n+ junction region 24 and the n+ junction region 25. A p+ junction region 27 may be formed within the p-type substrate 20, and spaced apart from the n+ junction region 25 by a distance.

An insulating layer 28 (e.g., an STI) may be formed within the n-well 21 between the n+ junction region 22 and the p+ junction region 23, between the p+ junction region 23 and the n+ junction region 24 and within the p-type substrate 20 between the n+ junction region 25 and the p+ junction region 27.

An input/output terminal I/O may be connected to the n+ junction region 22 and the p+ junction region 23. The p+ junction region 27, the gate electrode 26, and the n+ junction region 25 may be connected to a common ground VSS.

Referring to FIG. 3B, the gate electrode 26, the n+ junction region 24 and the n+ junction region 26 of FIG. 3A may form a gate, a drain and a source of an NMOS transistor, respectively. The p-type substrate 20, the n+ junction region 25 and the n-well 21 may form a base, an emitter and a collector of a parasitic npn transistor Q1, respectively. The n-well 21, the p-type substrate 20 and the p+ junction region 23 may form a base, a collector and an emitter of a parasitic pnp transistor Q2, respectively. A parasitic resistor Rp may be formed between the p-type substrate 20 and the p+ junction region 27, for example, between the base and emitter of the parasitic npn transistor Q1. A parasitic resistor Rn may be formed between the n-well 21 and the n+ junction region 22, for example, between the base and emitter of the parasitic pnp transistor Q2.

Referring to FIG. 3A, when static electricity is generated, a higher voltage may be applied to the input/output terminal I/O. A reverse-biased pn junction between the n+ junction region 24 and the p-type substrate 20 may breakdown, and a trigger current may flow from the n+ junction region 22 through the n-well 21, the n+ junction region 24, the p-type substrate 20, and the p+ junction region 27 to ground VSS. A pn junction between the p-type substrate 20 and the n+ junction region 25 and a pn junction between the n-well 21 and the p+ junction region 23 may be forward-biased, so that an ESD current may flow from the input/output terminal I/O through the p+ junction region 23, the n-well 21, the n+ junction region 22, the p-type substrate 20 and the n+ junction region 25 to ground VSS.

For example, when static electricity is generated resulting in a higher voltage being applied to the input/output terminal I/O, the trigger current may flow through the drain-gate of the NMOS transistor and the collector-base of the parasitic npn transistor Q1 and the parasitic resistor Rp of FIG. 3B. This may also result in a voltage of the base of the parasitic npn transistor Q1 and the gate of the NMOS transistor to increase. The NMOS transistor, the parasitic npn transistor Q1 and the parasitic pnp transistor Q2 may be switched on, so that the ESD current may flow through the parasitic pnp transistor Q2 and the parasitic npn transistor Q1. For example, the SCR for ESD protection may perform ESD protection to discharge ESD current from the input/output terminal V/O to ground VSS. However, even though the SCR configured as shown in FIGS. 3A and 3B has improved current drivability per unit area as compared to the NMOS type SCR for ESD protection, the trigger voltage Vt may be higher than the NMOS type SCR for ESD protection and/or the holding voltage Vh may be too low. If the trigger voltage Vt is higher than the NMOS type SCR for ESD protection, an internal element within a chip such as an out driver may be triggered first when static electricity is discharged, which may cause damage to the internal element. If the holding voltage Vh is too low, the internal element may be latched up during normal operation.

In this example, the holding voltage Vh may be a minimum voltage allowing the ESD protection to be performed. Such an SCR for ESD protection may have a multi-finger structure for handling a higher voltage and/or current of higher capacitance, which may not have uniform turn-on characteristics.

When a trigger voltage of each finger is changed, the corresponding transistor of the finger may be switched on to be associated with the discharge of higher voltage. As a result, the multi-finger structure may be utilized less effectively.

The related art SCR for ESD protection, when configured to have the multi-finger structure, may not have uniform trigger voltages in all or substantially all fingers.

### SUMMARY OF THE INVENTION

At least one example embodiments of the present invention provides an SCR for ESD having improved operating characteristics with a lower trigger voltage, a higher holding voltage, and/or is capable of securing more uniform fingers in a multi-finger SCR.

At least one example embodiment of the present invention is directed to an SCR for ESD protection. The SCR for ESD protection may include a first well and a second well formed within a substrate. The substrate may have a first conductivity type and the first and second wells may have a second conductivity type. A first junction region having the second conductivity type may be formed within a region of the first well, and a second junction region having the first conductivity type may be formed within the first well spaced apart from the first junction region. A third junction region of the second conductivity type may include a first portion formed within the first well and a second portion formed within the substrate. A fourth junction region of the second conductivity type may include a first portion formed within the second well and a second portion formed within the substrate. A gate electrode may be formed on the substrate between the third junction region and the fourth junction region. A fifth junction region of the first conductivity type may be formed within a region of the substrate.

In another example embodiment of the present invention, an SCR may include at least one finger. Each of the at least one fingers may include a first well formed within a portion of a substrate. A second well may be formed within the substrate and spaced apart from the first well. A first junction region may be formed within a portion of the first well, and a second junction region may be formed within the first well, spaced apart from the first junction region. A third junction region may include a first portion formed within the first well and a second portion formed within the substrate. A fourth junction region may include a first portion formed within the second well and a second portion formed within the substrate. A gate electrode may be formed on the substrate between the third junction region and the fourth junction region. A fifth junction region may be formed within a portion of the substrate. The first well, the second well, the first junction region, the third junction region and/or the fourth junction region may have the same conductivity-type.

Another example embodiment of the present invention is directed to an SCR for ESD protection. The SCR may include a plurality of fingers formed within a substrate of a first conductivity type. A substrate coupling unit may connect the fingers to each other. Each of the fingers may further include a first well of a second conductivity type formed within a region of the substrate. A first junction region of the second conductivity type may be formed within a region of the first well, and a second junction region of the first conductivity type may be formed within a region of the first well. A third junction region of the second conductivity type may include a first portion formed within the first well and a second portion formed within the substrate. A fourth junction region of the second conductivity type may be formed within the substrate spaced apart from the third junction region. A gate electrode may be formed on the substrate between the third junction region and the fourth junction region, and a fifth junction region of the first conductivity type may be formed within the substrate spaced apart from the first well. A sixth junction region of the first conductivity type may be formed within the substrate between the fifth junction region and the fourth junction region. At least one diode may be formed between the fourth junction region and the fifth junction region.

According to at least some example embodiments of the present invention, the first conductivity type may be a p-type conductivity and the second conductivity type may be an n-type conductivity, or vice-versa.

According to at least some example embodiments of the present invention, an insulating layer may be formed between the first junction region and the second junction region, between the second junction region and the third junction region, and between the fourth junction region and the fifth junction region, respectively. The substrate coupling unit may be a conductive metal line. Each set of adjacent the fingers and a finger adjacent to the finger may share a common first well and first junction region.

### BRIEF DESCRIPTION OF THE DRAWINGS

The present invention will become more apparent from the following description of example embodiments as illustrated in the accompanying drawing.

FIG. 1A is a cross-sectional view illustrating the structure of a conventional grounded-gate NMOS transistor for ESD protection;

FIG. 1B is an equivalent circuit of the grounded-gate NMOS transistor for ESD protection of FIG. 1A;

FIG. 2 is a graph illustrating the current-voltage characteristics of the grounded-gate NMOS transistor for ESD protection in response to an occurrence of static electricity;

FIG. 3A is a cross-sectional view illustrating the structure of a conventional SCR for ESD protection;

FIG. 3B is an equivalent circuit of the SCR for ESD protection of FIG. 3A;

FIG. 4A is a cross-sectional view illustrating the structure of an SCR for ESD protection according to an example embodiment of the present invention;

FIG. 4B is an equivalent circuit of the SCR for ESD protection of FIG. 4A;

FIG. 5A is a cross-sectional view illustrating the structure of an SCR for ESD protection in according to another example embodiment of the present invention;

FIG. 5B is an equivalent circuit of the SCR for ESD protection of FIG. 5A;

FIG. 6A is a cross-sectional view illustrating the structure of a multi-finger SCR for ESD protection according to another example embodiment of the present invention; and

FIG. 6B is an equivalent circuit of the SCR for ESD protection of FIG. 6A.

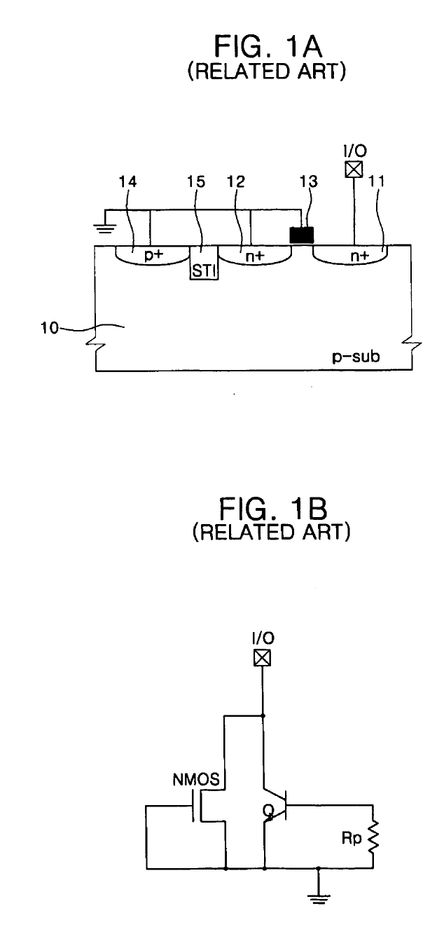

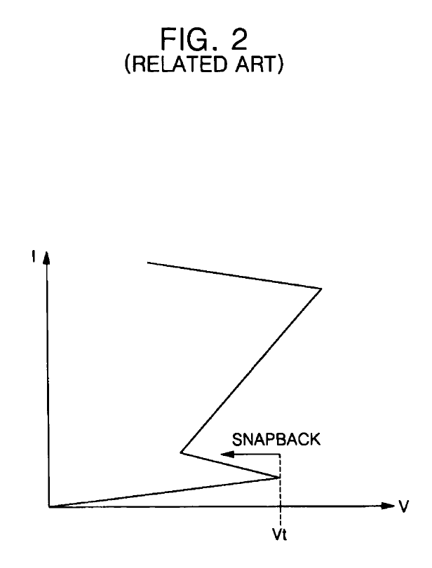

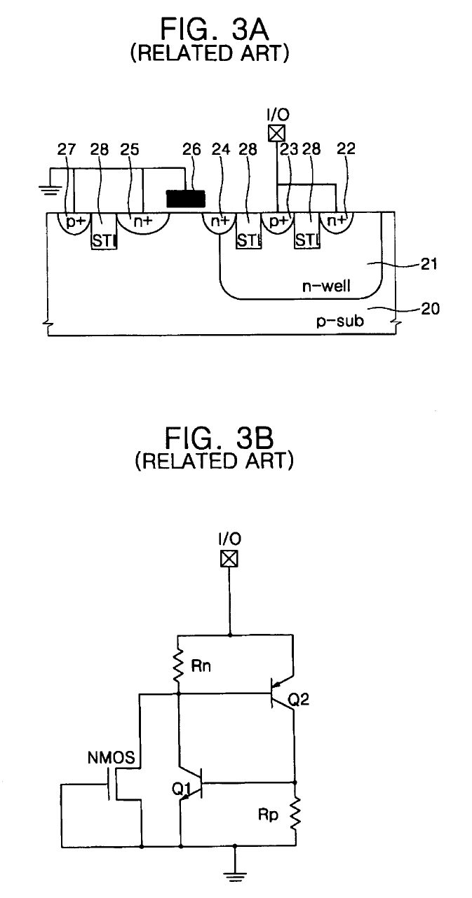

### DETAILED DESCRIPTION OF EXAMPLE EMBODIMENTS OF THE PRESENT INVENTION

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

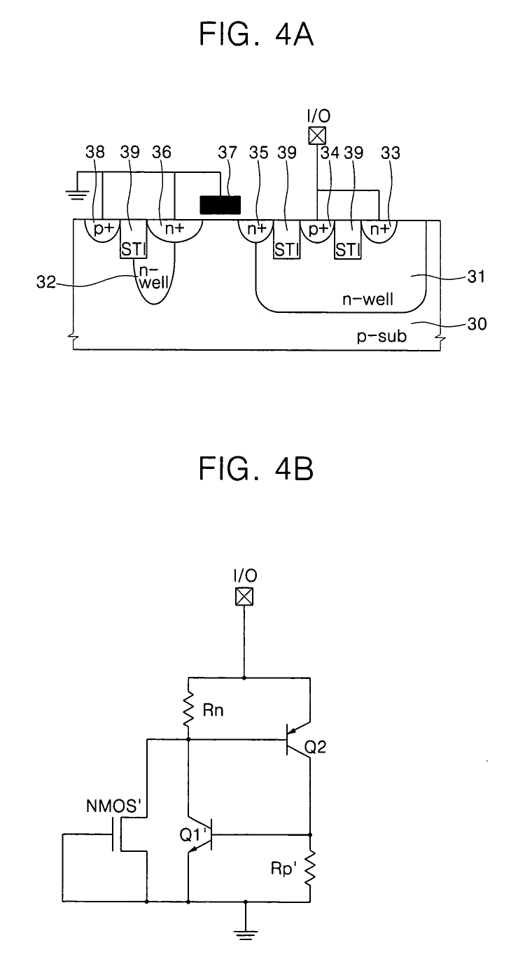

FIG. 4A shows the structure of an SCR for ESD protection according to an example embodiment of the present invention. FIG. 4B shows an equivalent circuit of the SCR for ESD protection of FIG. 4A.

Referring to FIG. 4A, an n-well 31 may be formed within a region of a p-type substrate 30. An n-well 32 may be formed within the p-type substrate 30, a distance apart from the n-well 31.

An n+ junction region 33, and a p+ junction region 34 may be formed within the n-well 31. The n+ junction region 30 and p+ junction region 34 may be spaced apart from each other by a distance. An n+ junction region 35 may be formed at an interface of the p-type substrate 30 and n-well 31, at least partly within the n-well 31 and at least partly within the p-type substrate 30.

An n+ junction region 36 may be formed at an interface of the n-well 32 and the p-type substrate 30, at least partly within the n-well 32 and/or at least partly within the p-type substrate 30. A gate electrode 37 may be formed on a surface of the p-type substrate 30 between the n+ junction region 35 and the n+ junction region 36. A p+ junction region 38 may be formed within the p-type substrate 30, spaced apart from the n-well 32, and the n+ junction region 36 by a distance.

An insulating layer 39 (e.g., an STI) may be formed within the n-well 31 between the n+ junction region 33 and the p+ junction region 34, within the n-well 31 between the p+ junction region 34 and the n+ junction region 35, and partly within the n-well 32 and the p-type substrate 30 between the n+ junction region 36 and the p+ junction region 38.

An input/output terminal I/O may be connected to the n+ junction region 33 and the p+ junction region 34. The p+ junction region 38, the gate electrode 37 and the n+ junction region 36 may be connected to a common ground VSS.

Referring to FIG. 4B, the gate electrode 37, the n+ junction region 35 and the n+ junction region 36 of FIG. 4A may form a gate, a drain and a source of an NMOS transistor NMOS′, respectively. The p-type substrate 30, the n+ junction region 36 and the n-well 31 may form a base, an emitter and a collector of a parasitic npn transistor Q1′, respectively. The n-well 31, the p+ junction region 34 and the p-type substrate 30 may form a base, an emitter and a collector of a parasitic pnp transistor Q2. A parasitic resistor Rp′, may be formed between the p-type substrate 30 and the p+ junction region 38, for example, between the base and emitter of the parasitic npn transistor Q1′. A parasitic resistor Rn may be formed between the n-well 31 and the n+ junction region 33, for example, between the base and emitter of the parasitic pnp transistor Q2.

The SCR for ESD protection, according to example embodiments of the present invention may have the n-well 32 formed below the n+ junction region 36, which may serve as an emitter region of the parasitic npn transistor Q1′ and a source region of the NMOS transistor NMOS′. This may increase resistance of the current path of the trigger current.

For example, the width of the trigger current path between the n+ junction region 35, the p-type substrate 30 and the p+ junction region 38 may be reduced and the length of the current path may be increased by the n-well 32, and the resistance of the trigger current path may be increased. The n-well 32 may also increase the resistance of the parasitic resistor Rp′ between the ground voltage and the base of the parasitic npn transistor Q1′.

In addition, the source region of the NMOS transistor NMOS′ and the emitter region of the parasitic npn transistor Q1′ may be extended by the n-well 32, which may increase current gain P of the parasitic npn transistor Q1′ and/or the NMOS transistor NMOS′. This may reduce the trigger voltage Vt.

Referring to FIG. 4B, when static electricity is generated resulting in an applied voltage to the input/output terminal I/O, a trigger current may flow through the drain-gate of the NMOS transistor NMOS′, the collector-base of the parasitic npn transistor Q1′ and the parasitic resistor Rp′. Voltages of the base of the parasitic npn transistor Q1′ and the gate of the NMOS transistor NMOS′ may reach the trigger voltage Vt faster in response to the increased parasitic resistance Rp′. Accordingly, the parasitic npn transistor Q1′ and/or the parasitic pnp transistor Q2 may be switched on faster, which may cause the ESD current to flow faster.

The bipolar junction transistor (BJT) current gain P of the npn transistor Q1′ increased by the n-well 32 may increase the current drivability, which may reduce the trigger voltage Vt.

As described above, the SCR for ESD protection, according to example embodiments of the present invention, may have the n-well 32 so that the parasitic npn transistor Q1′ and/or the parasitic pnp transistor Q2 may be switched on by a lower trigger voltage Vt. For example, the SCR for ESD protection may perform ESD protection operation in response to a lower applied voltage.

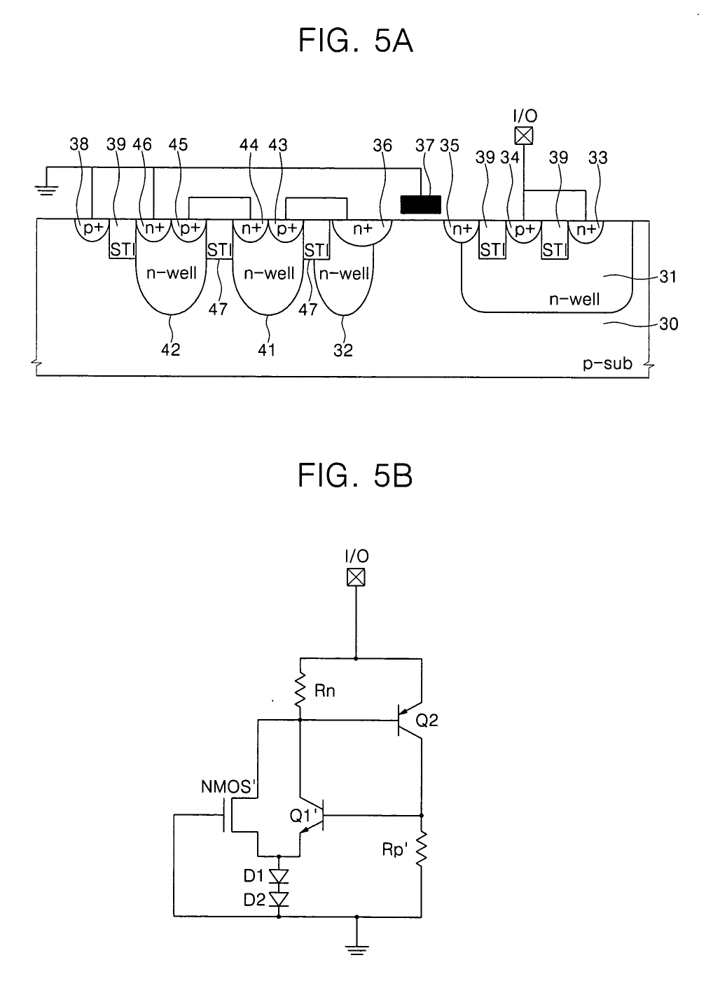

The SCR for ESD protection, according to example embodiments of the present invention, may have a lower trigger voltage Vt as compared to related art SCRs for ESD protection. However, the SCR for ESD protection, according to at least some example embodiments of the present invention, may have a lower holding voltage Vh, which may result in latch-up. The possibility of latch-up may be reduced in SCRs according to at least some example embodiments of the present invention, for example, as illustrated in FIGS. 5A and 5B.

FIG. 5A shows an SCR for ESD protection according to another example embodiment of the present invention. FIG. 5B shows an equivalent circuit of the SCR for ESD protection of FIG. 5A.

Referring to FIG. 5A, the same or substantially the same method as described above with reference to FIG. 4A may be used to form an SCR for ESD protection of FIG. 5A. The SCR of FIG. 5A may include a parasitic npn transistor Q1′, a parasitic pnp transistor Q2 and/or parasitic resistors Rp′ and Rn which may be formed using n-wells 31 and 32, n+ junction regions 33, 35 and 36, p+ junction regions 34 and 38 and a gate electrode 37. However, in FIGS. 5A and 5B, at least one pn junction diode may be connected in series between ground VSS and an emitter of the parasitic npn transistor Q1 ′ and a source of an NMOS transistor NMOS′.

For example, n-wells 41 and 42 may be formed within the p-type substrate 30 between the n-well 32 and the p+ junction region 38. A p+ junction region 43 and an n+ junction region 44 adjacent to the p+ junction region 43 may be formed within the n-well 41. A p+ junction region 45 and an n+ junction region 46 adjacent to the p+ junction region 45 may be formed within the n-well 42.

An insulating layer 47 (e.g., an STI) may be formed between the n-well 31 and the n-well 41, and between the n-well 41 and the n-well 42.

The p+ junction region 43 within the n-well 41 may be connected to the n+ junction region 36, to which the ESD current may flow. The p+ junction region 45 within the n-well 42 may be connected to the n+ junction region 44 within the n-well 41, to which the ESD current may flow.

The n+ junction region 46 within the n-well 42, the gate electrode 37, and the p+ junction region 38 may be connected to ground VSS to discharge the ESD current Ie.

Referring to FIG. 5B, in the same or substantially the same manner as FIG. 4B, the gate electrode 37, the n+ junction region 35 and the n+ junction region 36 of FIG. 5A may form a gate, a drain and a source of the NMOS transistor NMOS′, respectively. The p-type substrate 30, the n+ junction region 36 and the n-well 31 may form a base, an emitter and a collector of the parasitic npn transistor Q1′, respectively. The n-well 31, the p+ junction region 34 and the p-type substrate 30 may form a base, an emitter and a collector of the parasitic pnp transistor Q2, respectively.

The n-well 41, the p+ junction region 43 and the n+ junction region 44 may form a first pn junction diode D1 connected to an emitter region of the parasitic npn transistor Q1′ and a source region of the NMOS transistor. The n-well 42, the p+ junction region 45 and the n+ junction region 46 may form a second pn junction diode D2 connected between ground VSS and the first pn junction diode D1 of the parasitic npn transistor Q1′.

For example, the first and second pn junction diodes D1 and D2 may be serially connected between ground VSS and the emitter of the parasitic npn transistor Q1′ and the source of the NMOS transistor NMOS′.

The SCR for ESD protection, according to at least some example embodiments of the present invention, may reduce a holding voltage Vh.

Referring to FIG. 5B, when static electricity is generated resulting in an applied voltage, the ESD current generated by the trigger current may flow through the parasitic pnp transistor Q2, the NMOS transistor, the parasitic npn transistor Q1, and the first and second pn junction diodes D1 and D2.

When the voltage applied to the SCR is greater than or equal to the sum of each threshold voltage of the pn junction diodes, the ESD current of the same or substantially the same amount as in the conventional art may flow through the SCR.

The holding voltage Vh may be increased by the sum of each threshold voltage of the pn junction diodes.

The example embodiment shown in FIG. 5A may have two pn junction diodes to increase the holding voltage of the SCR for ESD protection. However, the number of pn junction diodes may be adjusted according to the holding voltage.

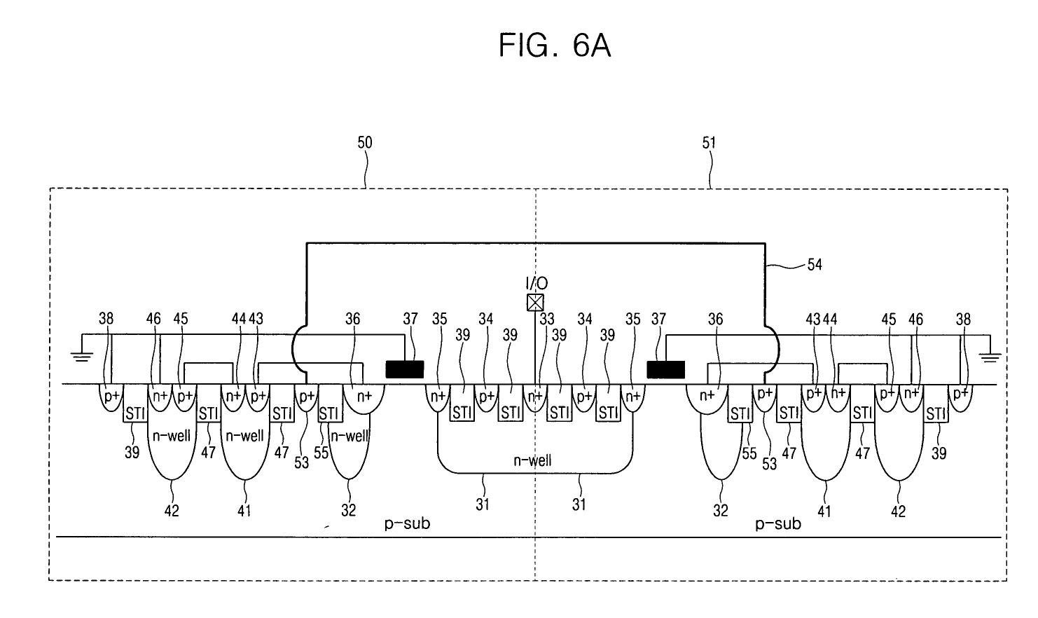

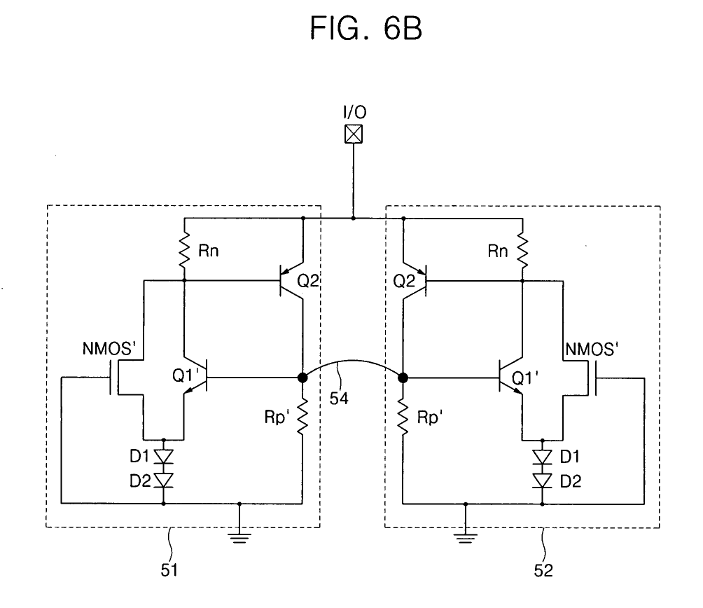

FIG. 6A shows the structure of a multi-finger SCR for ESD protection according to an example embodiment of the present invention. FIG. 6B shows an equivalent circuit of the multi-finger SCR for ESD protection of FIG. 6B.

Referring to FIG. 6A, the multi-finger SCR for ESD protection has fingers 51 and 52 symmetric about an input/output terminal I/O. Each of the fingers 51 and 52 may have an SCR for ESD protection formed in the same or substantially the same manner as FIG. 5A, except that the multi-finger SCR of FIG. 6A may further include a substrate coupling unit 54 for coupling fingers 51 and 52.

Each of the fingers 51 and 52 may form a parasitic npn transistor Q1′, the parasitic pnp transistor Q2 and the parasitic resistors Rp′ and Rn using the n-wells 31, 32, 41, and 42, the n+ junction regions 33, 35, 36, 44, and 46, the p+ junction regions 34, 38, 43, and 45 and the gate electrode 37 in the same or substantially the same method as FIG. 5A. The n-wells 31 and the n+ junction regions 33 of the fingers 51 and 52 may be merged so that the adjacent fingers 51 and 52 may share common n-wells 31 and n+ junction regions 33.

A p+ junction region 53 may be formed within the p-type substrate 30 between the n-well 41 forming the first pn junction diode D1 and the n-well 32 forming the emitter of the parasitic npn transistor Q1′. The p+ junction regions 53 of the fingers 51 and 52 may be electrically connected to each other via a metal line 54.

Each of the fingers 51 and 52 may have an insulating layer 55 (e.g., an STI) formed between the p+ junction region 53 and the n-well 32.

In this example embodiment, any material having conductivity such as copper, aluminum or other suitable metal or alloy, may be utilized for the metal line.

Referring to FIG. 6B, each of the fingers 51 and 52 of FIG. 6A may form the NMOS transistor NMOS′, the parasitic npn transistor Q1′, the parasitic pnp transistor Q2, and the parasitic resistors Rp and Rn, and the metal line 54 may connect the gate of NMOS transistor NMOS′, and the base of the parasitic npn transistor Q1′ of each of the fingers 51 and 52.

The multi-finger SCR for ESD protection according to at least this example embodiment of the present invention may increase the uniformity of the switch-on characteristics of the fingers 51 and 52.

Referring to FIG. 6B, when the breakdown is generated in a particular finger 51 due to, for example, static electricity, some trigger current may be applied to the base of the parasitic npn transistor Q1′ and the gate of the NMOS transistor NMOS′ of the finger 52 where breakdown may not be generated through the metal line 54. Accordingly, voltages of the parasitic npn transistor Q1′ and the NMOS transistor NMOS′ of the finger 52 where the breakdown is not generated may be increased more rapidly by the current induced from the finger 51 where the breakdown has been generated. As a result, the generation of the breakdown in all of the fingers 51 and 52 may become more uniform, so that the switch-on characteristics of the fingers 51 and 52 may become more uniform.

Example embodiments of the present invention as described above with respect to a positive transient; however, example embodiments of the present invention may be applied to structures of an SCR for ESD protection corresponding to a negative transient.

An SCR for ESD protection according to example embodiments of the present invention may lower a trigger voltage using a lower-concentration well, which may determine a trigger voltage and may be formed in an emitter region of the transistor. The SCR for ESD protection according to example embodiments of the present invention also increase a holding voltage using at least one diode, thereby enhancing the operating characteristics of the SCR for ESD protection.

A multi-finger SCR for ESD protection, according to example embodiments of the present invention, may have a substrate coupling unit to secure more uniform switch-on between the fingers.

Example embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A silicon controlled rectifier (SCR) comprising:
a substrate of a first conductivity type;
a first well of a second conductivity type formed within a region of the substrate;
a second well of the second conductivity type formed within the substrate and spaced apart from the first well,
a first junction region of the second conductivity type formed within a region of the first well, and receiving an external input;
a second junction region of the first conductivity type formed within the first well, spaced apart from the first junction region and receiving the external input;
a third junction region of the second conductivity type formed partly within the first well and partly within the substrate;
a fourth junction region of the second conductivity type formed partly within the second well and partly within the substrate, and coupled to a ground terminal;
a gate electrode formed on the substrate between the third junction region and the fourth junction region, and coupled to the ground terminal; and
a fifth junction region of the first conductivity type formed within a region of the substrate, and coupled to the ground terminal.

2. The SCR according to claim 1, further including,
a first insulating layer formed between the first junction region and the second junction region,
a second insulating layer formed between the second junction region and the third junction region, and
a third insulating layer formed between the fourth junction region and the fifth junction region.

3. The SCR according to claim 1, further including,
at least one diode, the at least one diode including,
a third well of the second conductivity type formed between the fourth junction region and the fifth junction region,
a sixth junction region of the first conductivity type formed within the third well, and connected to the fourth junction region, and
a seventh junction region formed within a region adjacent to the sixth junction region of the third well, wherein
the sixth junction region of each diode is connected to one of the fourth junction region and the seventh junction region of an adjacent diode, the fourth junction region being where an electrostatic discharge current is input, and
the seventh junction region is connected to one of a sixth junction region of the adjacent diode and to ground, the sixth junction region being where the electrostatic discharge current is output.

4. The SCR according to claim 3, further including,
a first insulating layer formed between the third wells of the adjacent diodes,
a second insulating layer formed between the sixth junction region and the seventh junction region of the diode, and
a third insulating layer formed between the diode and the fourth junction region, respectively.

5. The SCR according to claim 1, wherein the first conductivity type is a p-type and the second conductivity type is an n-type.

6. The SCR according to claim 1, wherein the first conductivity type is an n-type and the second conductivity type is a p-type.

7. A silicon controlled rectifier (SCR) comprising:
a substrate of a first conductivity type;
a plurality of fingers disposed within the substrate; and
a substrate coupling unit connecting the fingers to each other, wherein each of the fingers includes,
a first well of a second conductivity type formed within a region of the substrate,
a first junction region of the second conductivity type formed within a region of the first well,
a second junction region of the first conductivity type formed within a region of the first well,
a third junction region of the second conductivity type having a first portion formed within the first well and a second portion formed within the substrate,
a fourth junction region of the second conductivity type formed within the substrate and spaced apart from the third junction,
a gate electrode formed on the substrate between the third junction region and the fourth junction region,
a fifth junction region of the first conductivity type formed within the substrate spaced apart from the first well,
a sixth junction region of the first conductivity type formed within the substrate between the fourth junction region and the fifth junction region, and
at least one diode formed between the fourth junction region and the fifth junction region of the substrate.

8. The SCR according to claim 7, wherein the substrate coupling unit is a conductive metal line.

9. The SCR according to claim 7, wherein each set of adjacent fingers share a common first well and first junction region.

10. The SCR according to claim 7, wherein each of the plurality of fingers further includes,
a second well formed below the fourth junction region, the second well having a first portion formed within the substrate and a second portion formed within the second well.

11. The SCR according to claim 7, wherein the first conductivity type is a p-type and the second conductivity type is an n-type.

12. The SCR according to claim 7, wherein the first conductivity type is an n-type and the second conductivity type is a p-type.

13. A silicon controlled rectifier (SCR) comprising:
at least one finger, each of the at least one fingers including,
a first well formed within a portion of a substrate,
a second well formed within the substrate and spaced apart from the first well,
a first junction region formed within a portion of the first well,
a second junction region formed within the first well, spaced apart from the first junction region,
a third junction region including a first portion formed within the first well and a second portion formed within the substrate,
a fourth junction region including a first portion formed within the second well and a second portion formed within the substrate,
a gate electrode formed on the substrate between the third junction region and the fourth junction region, and
a fifth junction region formed within a portion of the substrate, wherein
the first well, the second well, the first junction region, the third junction region and the fourth junction region have the same conductivity-type.

14. The SCR according to claim 13, further including,
a first insulating layer formed between the first junction region and the second junction region,
a second insulating layer formed between the second junction region and the third junction region, and
a third insulating layer formed between the fourth junction region and the fifth junction region.

15. The SCR according to claim 13, further including,
at least one diode, the at least one diode including,
a third well formed between the fourth junction region and the fifth junction region,
a sixth junction region formed within a portion of the third well, and connected to the fourth junction region, and
a seventh junction region formed adjacent to the sixth junction region of the third well, wherein
the sixth junction region of each diode is connected to one of the fourth junction region and the seventh junction region of an adjacent diode, and
the seventh junction region is connected to a sixth junction region of the adjacent diode.

16. The SCR according to claim 15, further including,
a first insulating layer formed between third wells of adjacent diodes,
a second insulating layer formed between the sixth junction region and the seventh junction region of each diode, and
a third insulating layer formed between each diode and an adjacent fourth junction region.

17. The silicon controlled rectifier (SCR) of claim 13, wherein the at least one finger includes a plurality of fingers formed within the substrate, and the SCR further includes,
a substrate coupling unit connecting the plurality of fingers to each other.

18. The SCR according to claim 17, wherein each of the plurality of fingers further includes,
at least one diode, the at least one diode including,
a third well formed between the fourth junction region and the fifth junction region,
a sixth junction region formed within a portion of the third well, and connected to the fourth junction region, and
a seventh junction region formed adjacent to the sixth junction region of the third well, wherein
the sixth junction region of each diode is connected to one of the fourth junction region and the seventh junction region of an adjacent diode, and the seventh junction region is connected to a sixth junction region of the adjacent diode.

19. The SCR according to claim 18, wherein each set of adjacent fingers share a common first well and first junction region.

20. The SCR according to claim 17, wherein the substrate coupling unit is a conductive metal line.
